(19) United States
(12) Patent Application Publication
(10) Pub. No.: US 2024/0055244 A1
(43) Pub. Date: Feb. 15, 2024

(54) PULSED VOLTAGE COMPENSATION FOR PLASMA PROCESSING APPLICATIONS

(71) Applicant: Applied Materials, Inc., Santa Clara, CA (US)

(72) Inventors: Shreeram Jyoti DASH, San Jose, CA (US); Michael Thomas NICHOLS, Sunnyvale, CA (US)

(21) Appl. No.: 17/885,277

(22) Filed: Aug. 10, 2022

(51) Int. Cl. H01J 37/32

(52) U.S. Cl. CPC H01J 37/3299; H01J 2237/24564; H01J 2237/3341

(57) ABSTRACT

Embodiments provided herein generally include apparatus, e.g., plasma processing systems, and methods for the plasma processing of a substrate in a processing chamber. Some embodiments are directed to a method for waveform generation, which generally includes delivering a first waveform with an associated setpoint from an energy source; detecting at least one characteristic of the first waveform; estimating a voltage decay during a portion of a pulse during the first waveform; calculating a compensation factor; and adjusting the at least one characteristic using the compensation factor to adjust a voltage decay.

### BACKGROUND

### Field

Embodiments of the present disclosure generally relate to a system used in semiconductor device manufacturing. More specifically, embodiments of the present disclosure relate to a plasma processing system used to process a substrate.

### Description of the Related Art

Reliably forming high aspect ratio features is one of the key technology challenges for manufacturing the next generation of semiconductor devices. High aspect ratio openings used to form the features are typically formed using a plasma-assisted etch process, such as a reactive ion etch (RIE) process capable of directionally controlled (i.e., anisotropic) material removal to transfer a pattern from a mask layer to exposed portions of the substrate surface there beneath. As feature sizes continue to shrink and pattern density continues to increase, the degree of anisotropy and within-substrate processing uniformity of the RIE process are critical factors in forming closely spaced (fine pitched) high aspect ratio openings.

For etching processes where the plasma ions play a major role, ion energy control is always challenging the semiconductor equipment industry. In a typical plasma-assisted etching process, the substrate is positioned on an electrostatic chuck (ESC) disposed in a processing chamber, a plasma is formed over the substrate, and ions are accelerated from the plasma towards the substrate across a plasma sheath, i.e., region depleted of electrons, formed between the plasma and the surface of the substrate. Traditionally, radio frequency (RF) substrate biasing methods, which use sinusoidal RF waveforms to excite the plasma and form the plasma sheath, have been unable to desirably form these smaller device feature sizes. Recently, it has been found that the delivery of high voltage direct current (DC) pulses to one or more electrodes within a processing chamber can be useful in desirably controlling the plasma sheath formed over the surface of the substrate.

During the plasma processing of a substrate, the voltage pulse will typically be configured to generally include a sheath collapse stage, an ion current stage, and a sheath formation stage that is disposed between the sheath collapse stage and an ion current stage. The sheath collapse stage may be implemented by generating a positive voltage (e.g., 100 volts) to be used to collapse a sheath generated over a surface of the substrate disposed on a substrate support positioned in a processing chamber. During the ion current stage, ions within the processing chamber flow to the surface of the substrate due to a generated negative voltage (e.g., −1600 volts) that is applied to an electrode disposed adjacent to the substrate. The ion current stage may be accompanied by an associated voltage decay, also often referred to as “droop,” in the voltage pulse established on the substrate during this stage, which may cause a generally undesirable ion energy distribution function (IEDF). The amount of voltage decay that occurs during plasma processing may vary due to a number of factors, which include chamber pressure variance, process chemistry variance, and the applied voltage and source power.

Accordingly, there is a need in the art for apparatus and methods that provide improved control over characteristics of a plasma sheath formed over a substrate during the plasma-assisted processing of the substrate.

### SUMMARY

Embodiments herein provide plasma processing chambers and methods configured for fine-tuning and control over a plasma sheath formed during the plasma-assisted processing of a semiconductor substrate.

Some embodiments are directed to a method for waveform generation. The method generally includes delivering a first waveform with an associated setpoint from an energy source; detecting at least one characteristic of the first waveform using at least one sensor; determining a voltage decay value during a portion of a pulse during the first waveform by using the detected at least one characteristic and at least one stored voltage decay value function; determining a sheath coupling voltage value during the portion of the pulse of the first waveform by using the detected at least one characteristic and at least one stored sheath coupling voltage value function; calculating a compensation factor based on the determined voltage decay value and the determined sheath coupling voltage value; and adjusting the at least one characteristic using the compensation factor.

Some embodiments are directed to a method for waveform generation, comprising: delivering a first waveform with an associated setpoint from an energy source; detecting at least one characteristic of the first waveform using at least one sensor; determining a voltage decay value during a portion of a pulse provided within the first waveform by use of the detected at least one characteristic and at least one stored voltage decay value function; determining a sheath coupling voltage value during the portion of the pulse of the first waveform by use of the detected at least one characteristic and at least one stored sheath coupling voltage value function; calculating a compensation factor based on the determined voltage decay value and the determined sheath coupling voltage value; and adjusting at least one characteristic of the first waveform by applying the calculated compensation factor to the at least one characteristic of the first waveform.

Some embodiments are directed to a waveform generator. The waveform generator generally includes a sensor assembly coupled to the output of the pulser, wherein the sensor assembly comprises at least one sensor configured to detect at least one characteristic of a first waveform generated by the waveform generator; and a system controller coupled to the waveform generator. The system controller generally includes a processor and memory, wherein the memory includes instructions which when executed by the processor causes: an amount of voltage decay within a portion of a pulse during the first waveform to be determined using at least one stored voltage decay value formulation; an amount of a sheath coupling voltage within the portion of a pulse of the first waveform to be determined using at least one stored sheath coupling voltage value formulation; a compensation factor based on the determined amount of voltage decay and the determined amount of sheath coupling voltage to be calculated; and the at least one characteristic to be adjusted using the compensation factor to adjust a voltage decay.

Some embodiments are directed to a waveform generator, comprising: a sensor assembly coupled to an output of a pulser, wherein the sensor assembly comprises at least one sensor configured to detect at least one characteristic of a first waveform generated by the waveform generator; and a system controller coupled to the waveform generator. The system controller comprises: a processor and memory, wherein the memory includes instructions which when executed by the processor causes: an amount of voltage decay within a portion of a pulse during the first waveform to be determined using at least one stored voltage decay value function; an amount of a sheath coupling voltage within the portion of a pulse of the first waveform to be determined using at least one stored sheath coupling voltage value function; a compensation factor based on the determined amount of voltage decay and the determined amount of sheath coupling voltage to be calculated; and the at least one characteristic of the first waveform to be adjusted based on the application of the calculated compensation factor.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope and may admit to other equally effective embodiments.

FIG. 1 is a simplified schematic cross-sectional view of a processing system and a signal detection module, in accordance with certain embodiments of the present disclosure.

FIG. 2 illustrates an example of an under compensated voltage waveform established on a substrate, in accordance with certain embodiments of the present disclosure.

FIG. 3 is a process flow diagram illustrating a method of waveform generation, in accordance with certain embodiments of the present disclosure.

FIG. 4 illustrates an example of a compensated voltage waveform established on a substrate, in accordance with certain embodiments of the present disclosure.

FIG. 5A illustrates a curve representing a detected voltage pulse formed within a burst of pulses of a voltage waveform and a curve representing a plot of a portion of the voltage detected during the burst of pulses, in accordance with certain embodiments of the present disclosure.

FIG. 5B illustrates a curve representing a current detected during the delivery of the voltage pulse formed within the burst of pulses of the voltage waveform of FIG. 5A and a curve representing a plot of the current detected during the portion of the burst of pulses of FIG. 5A, in accordance with certain embodiments of the present disclosure.

FIG. 6A illustrates a voltage decay value curve for a waveform, in accordance with certain embodiments of the present disclosure.

FIG. 6B illustrates a plurality of plasma sheath coupling curves, in accordance with certain embodiments of the present disclosure.

FIG. 7 shows an example compensation factor as applied to a voltage waveform.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Certain aspects of the present disclosure are generally directed to techniques for generating a compensated voltage waveform for a plasma processing system. During the plasma processing of a substrate, the voltage waveform, which is provided to an electrode disposed within a plasma processing chamber, will typically be configured to include a sheath collapse stage and an ion current stage. The sheath collapse stage may be implemented by generating a positive voltage (e.g., 100 volts) to be used to collapse a plasma sheath generated over a surface of the substrate disposed on a substrate support positioned in a processing chamber. During the ion current stage, ions within a plasma formed in the processing chamber begin to flow to a surface of the substrate due to a negative voltage (e.g., >1000 volts) that is created by the application of a pulse voltage waveform to an electrode disposed adjacent to the substrate. The ion current stage may be accompanied by an associated voltage decay, or “droop,” which will typically cause an undesirable energy distribution function (IEDF) at the surface of the substrate. The amount of voltage decay that occurs during plasma processing may vary due to a number of factors, which include chamber pressure variance, process chemistry variance, and the applied voltage and source power. Due to the variance of the voltage decay between plasma processing chambers and processing systems as plasma processing recipes vary, there is a need to account for the voltage decay during plasma processing and to compensate for the decay accordingly.

In aspects of the current disclosure, a waveform generator may use a ramp during the ion current stage of a pulse to implement voltage compensation to narrow the IEDF, as described in more detail herein. The compensated voltage waveform can be generated by applying a calculated compensation factor to a waveform generated by a pulsed voltage source to correct for the voltage decay that is established on the substrate during plasma processing.

### Plasma Processing System Example

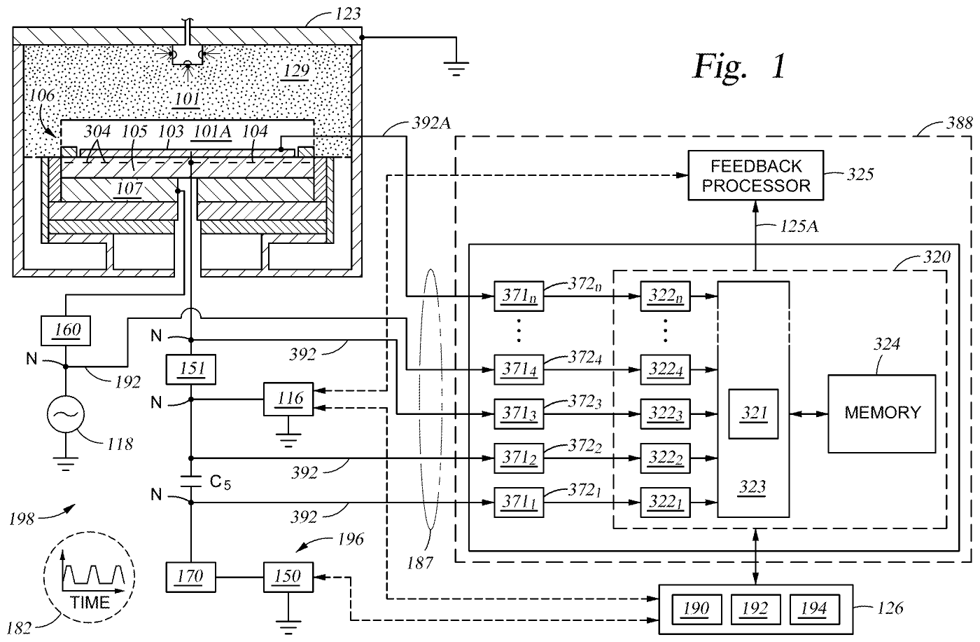

FIG. 1 is a simplified schematic cross-sectional view of a processing system and a signal detection module, in accordance with certain embodiments of the present disclosure. In some embodiments, the processing system is configured for plasma-assisted etching processes, such as a reactive ion etch (RIE) plasma processing. However, it should be noted that the embodiments described herein may be also be used with processing systems configured for use in other plasma-assisted processes, such as plasma enhanced deposition processes, for example, plasma-enhanced chemical vapor deposition (PECVD) processes, plasma-enhanced physical vapor deposition (PEPVD) processes, plasma-enhanced atomic layer deposition (PEALD) processes, plasma treatment processing or plasma-based ion implant processing, for example, plasma doping (PLAD) processing.

As shown, the processing system includes a processing chamber 100 and a signal detection module 388 that may be used to monitor and control characteristics of a plasma sheath 101a during substrate processing. The processing chamber 100 includes the signal detection module 388, a support assembly 136, and a bias module 198. The bias module 198 can include one or more pulse voltage (PV) waveform generators 150 and/or one or more RF generator assemblies 118. The support assembly 136 includes a support base 107 and a substrate support 105 disposed on and thermally coupled to a support base 107. As shown, the processing chamber 100 is configured to generate a capacitively coupled plasma by delivering a radio frequency (RF) signal to the support base 107 from the RF power supply 118. However, it is contemplated that the signal detection module 388 can be used with any number of processing chambers, support assemblies, and bias modules in order to facilitate monitoring and control over the plasma sheath 101a during substrate processing.

Here, electrical signals that can be used to determine one or more characteristics of the plasma sheath 101a are received by the signal detection module 388, which then communicates information relating to the electrical signals to the system controller 126 for use in controlling aspects of the plasma process. The system controller 126 may include a processor 190, a memory 192, and a support circuit 194. The processor 190 may be a general-purpose computer processor configured for use in an industrial setting for controlling the processing chamber and sub-processors related thereto. The memory 192, which is generally non-volatile memory, may include random access memory, read-only memory, floppy or hard disk drive, or other suitable forms of digital storage, local or remote. The support circuits 194 are conventionally coupled to the processor 190 and comprise a cache, clock circuits, input/output subsystems, power supplies, and the like, and combinations thereof. Software instructions (program) and data can be coded and stored within the memory 192 for instructing the processor 190. A software program (or computer instructions) readable by processor 190 in the system controller 126 determines which tasks are performable by the components in the processing system.

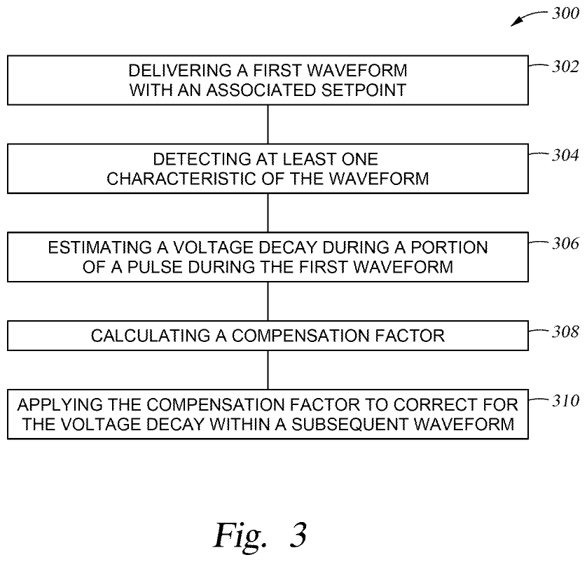

Typically, the program, which is readable by processor 190 in the system controller 126, may be stored in the memory 192, and includes code, which, when executed by the processor 190, performs tasks relating to the plasma processing schemes described herein. The program may include computer implemented instructions that are used to control the various hardware and electrical components within the processing system to perform the various process tasks and various process sequences used to implement the methods described herein. In one embodiment, the program includes instructions that are used to perform one or more of the operations described below in relation to FIG. 3.

Typically, the system controller 126 determines, based on the information received from the signal detection module 388, one or more characteristics of the plasma sheath 101a and compares the determined sheath characteristics to desired sheath characteristics. Based on the difference between the determined sheath characteristics to desired sheath characteristics, the system controller 126 may use the sheath compensation scheme described herein to adjust the one or more sheath characteristics, e.g., by changing a configuration of one or more of the pulsed voltage (PV) waveforms established at the bias electrode 104. For example, the system controller 126 may cause the PV waveform generator 150 to change one or more characteristics of a pulsed voltage waveform delivered to the bias electrode 104. In some embodiments, a second PV waveform generator 150 (not shown) is coupled to an edge electrode 115 and thus is configured to deliver one or more of the PV waveforms to the edge electrode 115. In this configuration, the system controller 126 may also cause the second PV waveform generator 150 to change one or more characteristics of a pulsed voltage waveform delivered to the edge electrode 115 during plasma processing.

In some embodiments, the RF generator assembly 118 delivers an RF signal to the support base 107 (e.g., power electrode or cathode) which may be used to generate (maintain and/or ignite) a plasma 101 in a processing region 129 disposed between the substrate support assembly 136 and the chamber lid 123. In some embodiments, the RF generator 118 is configured to deliver an RF signal having a frequency that is greater than 1 MHz or more, or about 2 MHz or more, such as about 13.56 MHz or more, to the support base 107.

In some embodiments, an RF generator 118 and an RF generator assembly 160 are configured to deliver a desired amount of a continuous wave (CW) or pulsed RF power, often referred to herein as the “source power,” at a desired substantially fixed sinusoidal waveform frequency to a support base 107 of the substrate support assembly 136 based on control signals provided from the system controller 126. During processing, the RF generator 118 and an RF generator assembly 160 are configured to deliver RF power (e.g., an RF signal) to the support base 107 disposed proximate to the substrate support 105, and within the substrate support assembly 136. The RF power delivered to the support base 107 is configured to ignite and maintain a plasma 101 containing the processing gases disposed within a processing region 129. In some embodiments, the RF generator assembly 118 may alternately be configured to deliver the RF signal to the chamber lid 123 to ignite and maintain a plasma 101 containing the processing gases disposed within a processing region 129.

FIG. 1 shows electrical connections between the signal detection module 388 and nodes N, connection points, and bias electrode 104, a first PV module 196, and an electrostatic chuck clamping network 116. To reduce visual clutter only one PV waveform generator 150 is illustrated in FIG. 1, however it should be noted that in embodiments herein, the signal detection module 388 is configured to receive electrical signals through electrical connections to nodes N, connection points, and elements within the bias module 198.

As shown, the signal detection module 388 is electrically coupled to individual electrical components found within the processing chamber 100 by use of a plurality of signal lines 387. The plurality of signal lines 387 include multiple signal traces 392 that are coupled to various electrical components within the processing chamber 100 and are configured to deliver electrical signals to signal detection elements found within the signal detection module 388. In general, the signal detection module 388 includes one or more input channels 372 and a fast data acquisition module 320. The one or more input channels 372 are each configured to receive electrical signals from a signal trace 392 and are electrically coupled to the fast data acquisition module 320. The received electrical signals can include one or more characteristics of waveforms established by the PV waveform generator 150 and/or the RF power supply 118.

The fast data acquisition module 320 includes one or more acquisition channels 322 that receive signal information from the individual components of the processing chamber 100a via the signal lines 387 and the one or more input lines 172. The fast data acquisition module 320 processes the received signal information to determine one or more characteristics of the waveforms generated by the bias module and communicates the processed signal information to the system controller 126.

Generally, the signal detection module 388 includes multiple input channels 372 that are each electrically coupled to a corresponding acquisition channel 322 of the fast data acquisition module 320. As shown in FIG. 1, the multiple input channels 372 are coupled to connection points that are positioned in various parts of the bias module 198 and the clamping network 116 to measure and collect electrical data from these connection points or nodes N during processing. In some embodiments, the multiple input channels 372 may also be coupled to various electrical sensing elements, such as one or more current sensors, which are configured to measure and collect electrical data at various points within the processing chamber 100.

Here, the fast data acquisition module 320 includes a plurality of acquisition channels 322, the data acquisition controller 323, and memory 324 (e.g., non-volatile memory). The data acquisition controller 323 is electrically coupled to an output of each of the acquisition channels 322 and is configured to receive the digitized voltage waveform from each of the acquisition channels 322. Further, algorithms stored within the memory 324 of the data acquisition controller 323 are adapted to determine one or more waveform characteristics of each of the waveforms by analyzing each of the digitized voltage waveforms. The analysis may include a comparison of information received in the digitized voltage waveform with information relating to one or more stored waveform characteristics that are stored in memory 324, as discussed further below.

The data acquisition controller 323 can include one or more of an analog-to-digital converter (ADC) (not shown), a processor 321, a communication interface (not shown), a clock (not shown), and an optional driver (not shown). The processor may be any general computing processor. Further, the processor may be a Field Programmable Gate Array (FPGA). The ADC converts the signal within the output waveforms from the analog domain to the digital domain, and the output digital signal of the ADC is provided to the processor 321 for processing. The processor 321 determines the one or more waveform characteristics of the output waveform by analyzing the output digital signal provided from the ADC.

The memory 324 may be any non-volatile memory. The data acquisition controller 323 may be electrically coupled with the memory 324 and is configured to cause waveform characteristics to be stored within the memory 324. In various embodiments, the memory 324 includes instructions executable by the data acquisition controller 323 to cause the data acquisition controller 323 to analyze the received output waveforms and/or transmit information corresponding to determined waveform characteristics based on the analysis of the received output waveforms. A waveform analyzer stored in memory 324 includes instructions executable by the data acquisition controller 323 and when executed, causes the data acquisition controller 323 to analyze the output waveforms to determine the waveform characteristics.

Information relating to the analyzed waveform characteristics can then be transmitted to one or more of a feedback processor 325 and/or the system controller 126. The analysis performed by the data acquisition controller 323 can include a comparison of the waveform characteristics and one or more waveform characteristic threshold values stored in memory 324. In some embodiments, the analysis is based on one or more electrical characteristics of the processing chamber 100 that are known and stored in memory.

In some embodiments of the process chamber 100, a sensor assembly 170 is disposed between the PV waveform generator 150 and one or more of the bias electrode 104. The sensor assembly 170 includes a current sensor, which may be an in-line current sensor or be disposed within the PV waveform generator 150.

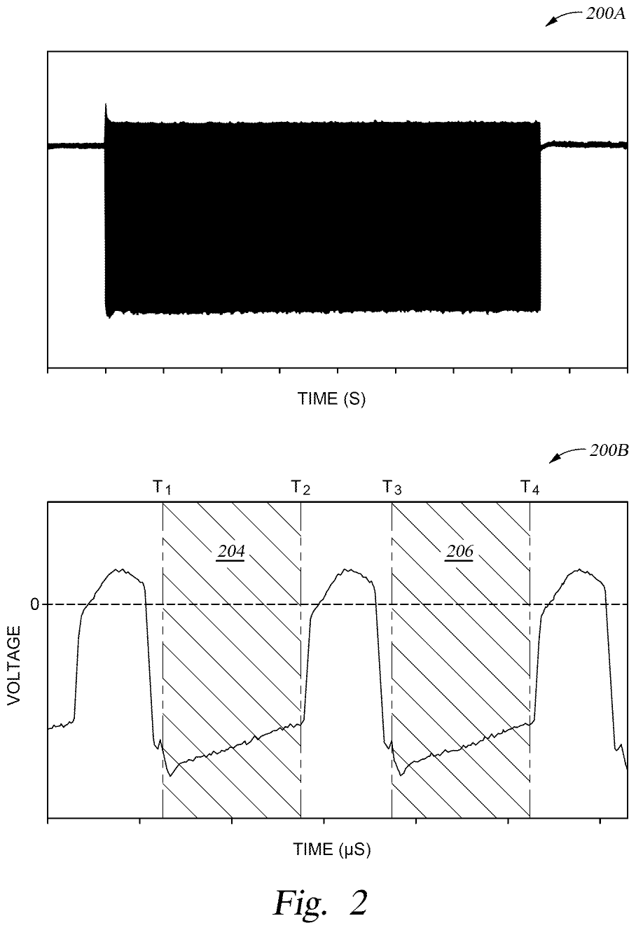

Generally, PV waveforms generated by the PV waveform generator 150 are configured to provide a nearly constant sheath voltage during a substantial portion of the PV waveform cycle (e.g., “ion current stage” in FIG. 2) that, in combination with the sheath thickness, enables the formation of a desirable ion energy distribution function (IEDF) at the surface of the substrate 103. As described in the methods below the ability to compensate the PV waveforms to account for the voltage decay at the bias electrode 104 enables fine-tuning, control, and tailoring of processing results across the surface of the substrate 103.

During processing, a plurality of PV waveforms are provided to the bias electrode 104, and eventually to a complex load within the processing chamber 100, by the PV waveform generator 150 of the bias module 198. The overall control of the delivery of the PV waveforms from the PV waveform generator 150 is controlled by use of signals provided from the signal detection module 388 and/or the system controller 126 as discussed below.

### Example Voltage Waveform

FIG. 2 illustrates an example of an under compensated voltage waveform established on a substrate during plasma processing, in accordance with certain embodiments of the present disclosure. In some embodiments, waveforms may be given as bursts instead of being continually applied during the performance of a plasma processing process performed on the substrate. The burst of pulses 200A is an example of a single burst of pulses established at the substrate 103 due to the delivery of a voltage waveform to the bias electrode 104 by the PV waveform generator 150. In some embodiments, the substrate 103 may be a wired version of a substrate 103, being referred to herein as a “wired wafer.” The wired wafer can be used to detect one or more characteristics of a waveform and plasma characteristics established on the wafer during plasma processing. In some embodiments, the wired wafer can be coupled to the signal detection module 388 via a wiring 392A so that information relating to one or more plasma processing characteristics (e.g., substrate voltage) can be determined within a plasma processing chamber, as shown in FIG. 1. The waveform 200B illustrates an example of two pulses, and portions of adjacent pulses on either side of the two pulses, generated within a portion of the burst of pulses 200A. In some embodiments, the waveform 200B is a PV waveform that includes a first portion (e.g., 204 portion between T₁ and T₂, and a 206 portion between T₃ and T₄) within each pulse that includes a positive slope (e.g., voltage per unit time), which relates to a “droop” in the voltage established on the substrate. The positive slope is formed on the substrate during the ion current stage of the PV waveform. The portions 204, 206 of the waveform 200B illustrate examples of under compensated voltage waveforms established on a substrate, which were measured by use of a wired wafer. A voltage decay step count, or staircase like ramp, includes a number of steps (e.g., steps) that are applied to the PV waveform at a fixed step voltage to form a negative voltage ramp that is used to compensate for the positive voltage ramp created by the voltage decay or droop. A voltage decay step count may not have been applied to the waveform 200B, and the waveform 200B may not be compensated.

In some embodiments, the portions 204, 206 of the waveform 200B in FIG. 2 represent example sampling windows used by the signal detection module 388 to detect and or determine characteristics of the “droop” within the voltage waveform established on the substrate 103 due to the voltage waveform generated by the PV waveform generator 150. In one example, the sampling window includes between about 50% and about 90% of a 400 kHz pulsed waveform. Several parameters may affect the 400 kHz “droop”, including plasma density/species, the baseline pulse voltage (PV) setpoint, temperature), and PV on-time. Several parameters may affect burst shape/spread, including burst on-time, source L2L pulsing.

The pulses within the waveform 200B generally includes two main stages: an ion current stage and a sheath collapse stage. Both the ion current stage and the sheath collapse stage portions of the waveform, which are established at the substrate 103, are shown in FIG. 2. At the beginning of the ion current stage, a drop in voltage at the substrate 103 is created, due to the delivery of a negative portion of a PV waveform (e.g., ion current portion) provided to the bias electrode 104 by the PV waveform generator 150, which creates a high voltage sheath above the substrate 103. The high voltage sheath allows the plasma generated positive ions to be accelerated towards the biased substrate. As more positive ions bombard the surface of the substrate, an amount of positive charge builds up on the surface of the substrate 103 over time. The increase in positive charge on the substrate's surface gradually increases the voltage of the substrate, or “substrate potential,” and thus creates the “droop.” As seen in FIG. 2, the voltage of the waveform 200B gradually and undesirably increases from a more negative voltage at the beginning of the ion current stage to a less negative voltage during the latter portion of the ion current stage. If uncontrolled, the gradual accumulation of positive charge on the surface of the substrate results in the gradual discharge of the high voltage sheath and chuck capacitance, slowly decreasing the sheath voltage and bringing the substrate potential closer to zero. The voltage difference between the beginning and end of the ion current stage determines the width of an ion energy distribution function (IEDF). The greater the difference in voltage, the wider the IEDF width, which is undesirable for a number of reasons, making reliably forming high aspect ratio features more difficult.

### Processing Monitoring and Control Examples

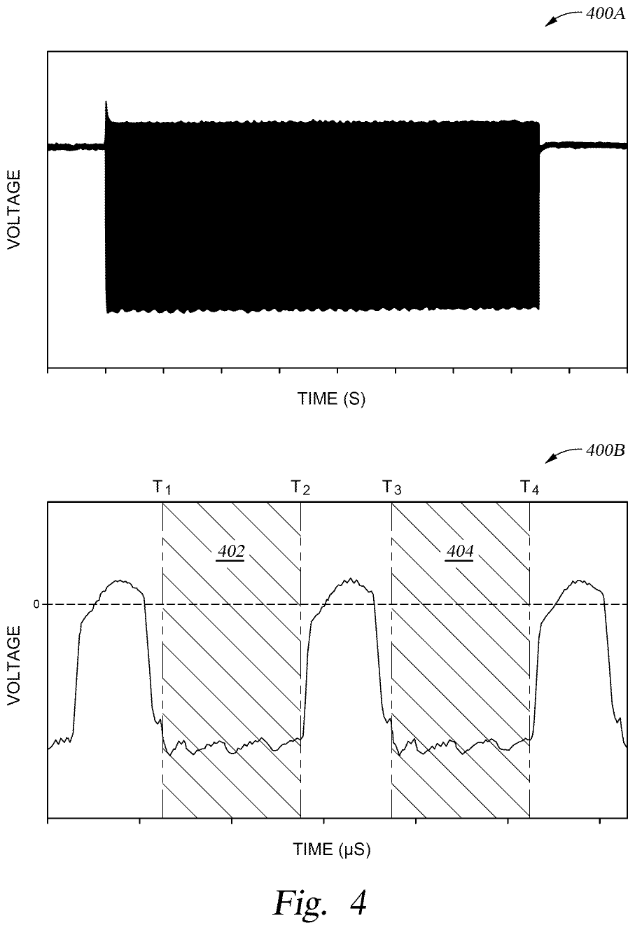

FIG. 3 is a process flow diagram illustrating a method 300 of waveform generation, in accordance with certain embodiments of the present disclosure. The blocks of the method 300 may be performed by use of a system controller 126, as described above. The method 300 may allow the waveform generator 150 to compensate for the voltage decay seen on a substrate 103, as is illustrated in the voltage waveform example illustrated in FIG. 4. The method 300 includes delivering a first waveform with an associated setpoint to an electrode within a process chamber, detecting at least one characteristic of the delivered first waveform, estimating a voltage decay during a portion of a pulse during the delivery of the first waveform to the electrode, calculating a compensation factor, and applying the compensation factor to correct for the voltage decay within a subsequent waveform that is delivered to the electrode.

FIG. 4 illustrates an example of a compensated voltage waveform established on a substrate 103 due to the delivery of a voltage waveform to an electrode (e.g., bias electrode 104) disposed adjacent to a substrate, in accordance with certain embodiments of the present disclosure. The burst of pulses 400A is an example of a burst of pulses of the compensated voltage waveform that is established at the substrate, which can be measured by use of a wired wafer. The waveform 400B illustrates an example of two pulses, and portions of adjacent pulses on either side of the two pulses, formed within the burst of pulses 400A. In some embodiments, the compensated voltage waveform illustrated by waveform 400B has a region 402 or region 404 within each pulse that has been adjusted in order to compensate for a voltage decay similar to the voltage decay illustrated in the waveform 200B.

To achieve monoenergetic ions and a narrower IEDF width during the ion current stage of the voltage waveform established at the substrate, operations are performed to compensate for the changing substrate potential during the ion current stage and create a substantially flat shaped region (e.g., near zero slope) of the established voltage waveform experienced by the substrate during plasma processing. An example of a voltage waveform experienced by the substrate during plasma processing is illustrated by the ion current stage portion of the waveform 400B in FIG. 4. To establish the substantially flat shaped region in the voltage waveform established at the substrate, a waveform that includes a negative slope during the ion current stage (i.e., ion current portion found in FIG. 4) can be delivered to the bias electrode 104 by the PV waveform generator 150. Driving, and or implementing the negative voltage slope at the bias electrode 104 is also known as current compensation, which can be created by use of a current source that is coupled to the bias electrode 104. The negative voltage slope implemented during ion current portion of the waveform 400B are created by increasing the amount of electrons provided to the bias electrode 104 by the PV waveform generator 150 to cancel the otherwise increasing field caused by the accumulating positive charges due to the incoming ions striking the substrate during plasma processing. Therefore, by determining the slope (dV/dt) of the voltage waveform established at the substrate 103, by use of the methods described herein, the system controller 126 can adjust the current provided by a current source and/or alter the characteristics of the PV waveform generated by the energy source (e.g., PV waveform generator 150) to thereby maintain a constant sheath potential throughout the ion current stage of the waveform established at the substrate 103. In some embodiments, a direct current (DC) supply current is used for implementing a ramp that has a desired slope during the ion current stage.

At block 302, a first waveform with an associated setpoint is delivered from an energy source (e.g., PV waveform generator 150) to an electrode. In some embodiments, the first waveform may be a high voltage pulse waveform, and the first waveform may establish a plasma sheath 101a. The associated setpoint may be a baseline process, that includes a waveform voltage setpoint during one or more stages of the delivery of a waveform (e.g., waveform 400B) to the electrode, a process pressure setpoint, an RF power setpoint, and a substrate temperature setpoint, and may include a PV waveform on-time setpoint (e.g., length of the ion current stage of the waveform).

At block 304, a sensor (e.g., current sensor in sensor assembly 170) may detect at least one characteristic of the first waveform generated by the PV waveform generator 150. The at least one characteristic may be the magnitude of a current detected by a current sensor (e.g., current transformer reading taken from the sensor). In some embodiments, the sensor may be an in-line sensor disposed between the energy source (e.g., PV waveform generator 150) and a bias electrode 104.

At block 306, a voltage decay during a portion of a pulse formed during the delivery of the first waveform may be estimated. Estimating the voltage decay may optionally include determining a voltage decay value during a portion of a pulse formed within the first waveform by using the detected at least one characteristic and at least one stored voltage decay value function stored in memory 192 of the system controller 126, and determining a sheath coupling voltage value during the portion of the pulse of the first waveform by using the detected at least one characteristic and at least one stored sheath coupling voltage value function. The sheath coupling voltage value is an empirically determined value that represents the capacitive coupling between the wired wafer and a biased electrode due to the delivery of voltage waveform to the electrode from an energy source (e.g., PV waveform generator 150). It is believed that the sheath coupling voltage value will vary as a function of one or more plasma processing parameters, which may include but are not limited to the magnitude of the applied voltage delivered during a pulse, process pressure and characteristics of the hardware in the processing chamber (e.g., capacitance of the dielectric layer disposed between the substrate and electrode). The sheath coupling voltage value can be determined, for each process chamber within a multi-chamber plasma processing system, by the system controller by use of an empirically derived function, or table of values, that were pre-determined by taking measurements on a previously processed substrate during plasma processing within a process chamber. In some embodiments, the measurements are made by use of a wired wafer that is able to at least detect a voltage established on the substrate during a plasma processing recipe performed in a process chamber.

In some embodiments of the method 300, the stored voltage decay value function and stored sheath coupling voltage value function may both have been previously determined and/or programed and stored in memory 192, and thus may be retrieved from memory 192 for use in estimating and correcting for the voltage decay that would be experienced by a substrate during the performance of a plasma processing recipe performed in a process chamber. In some embodiments of the method 300, the stored voltage decay value function and stored sheath coupling voltage value function may be determined using a wired wafer, as will be discussed below. The stored voltage decay value function and stored sheath coupling voltage value function may each include one value, or may each include more than one value. The stored voltage decay value function and stored sheath coupling voltage value function may each form a library or repository of data associated with multiple process conditions and recipes for a given processing chamber.

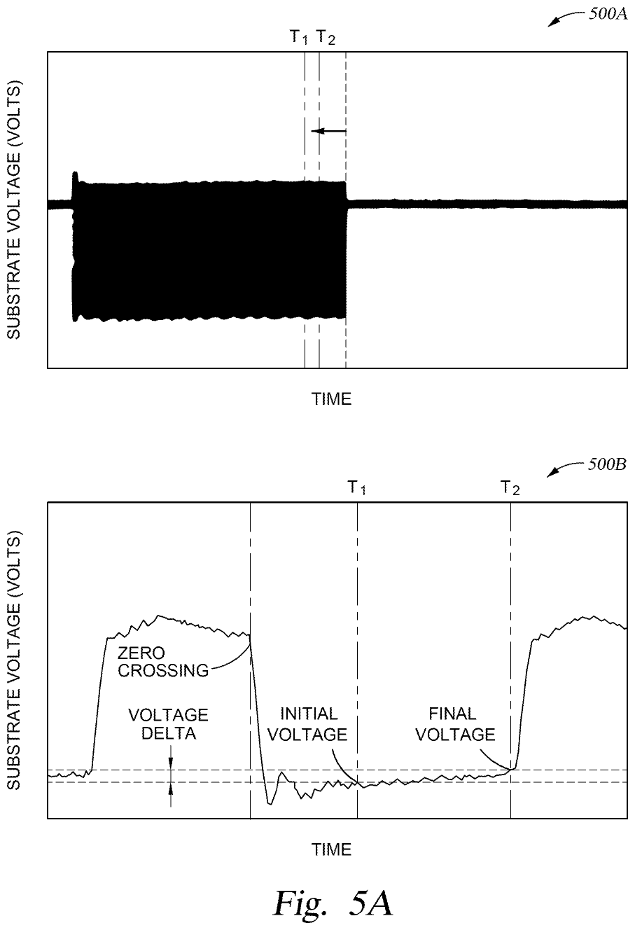

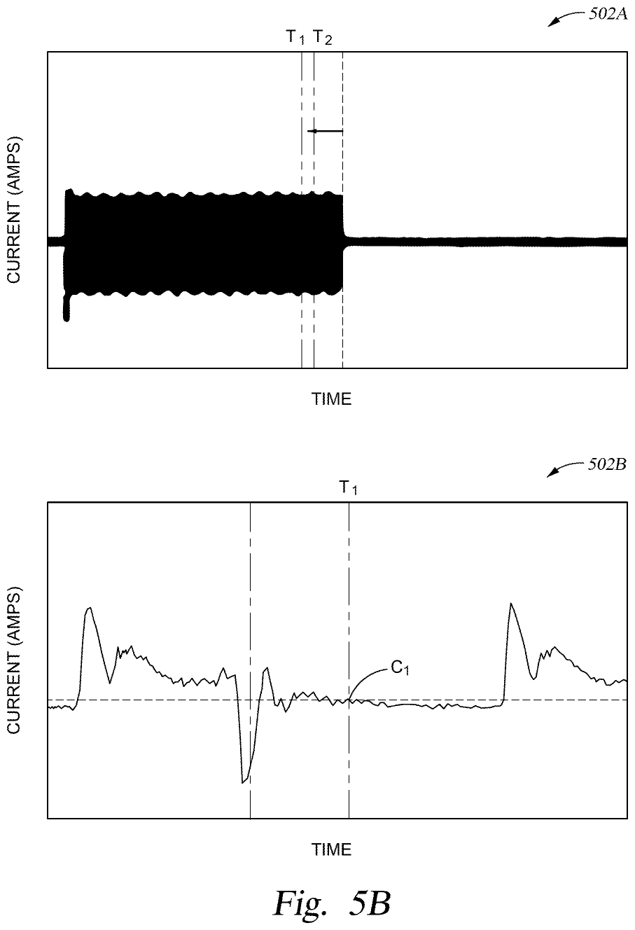

FIGS. 5A and 5B illustrate characteristics of a pulse of a voltage waveform established on a substrate 103 by use of a wired wafer and a sensing element found within the sensor assembly 170, in accordance with certain embodiments of the present disclosure. The burst of pulses 500A and 502A are examples of two different measurements used to characterize the electrical properties of a burst of pulses established at a substrate 103. The burst of pulses 500A includes a detected varying established voltage formed on a substrate due to the delivery of the voltage waveform within the burst of pulses to an electrode (e.g., bias electrode 104) by the PV waveform generator 150. The burst of pulses 502A includes a detected varying current flowing between the electrode and PV waveform generator 150 due to the delivery of the voltage waveform within the burst of voltage pulses to the electrode by the PV waveform generator 150. The waveform 500B (FIG. 5A) illustrates a time varying voltage measured during a portion of a pulse formed within the detected burst of pulses 500A, and the waveform 502B (FIG. 5B) illustrates a time varying current measured during the portion of the pulse formed within the detected burst of pulses 502A. In some embodiments, the waveform 500B is measured on a substrate 103 by use of a wired wafer. In some embodiments, it is desirable to perform similar measurements in each process chamber within a plasma processing system to characterize the actual electrical characteristics for each process chamber. In other embodiments, it is desirable to perform measurements in one process chamber within a plasma processing system and then utilize the measured electrical characteristics for that process chamber as the representative electrical characteristics for the other process chambers in the plasma processing system.

The method 300 may optionally include creating a function involving at least one voltage decay value and a function used to determine at least one sheath coupling voltage associated with a substrate during a plasma process. In some embodiments, the method 300 may include detecting an initial voltage value and a final voltage value established on a substrate 103 during a portion of a pulse (e.g., waveform 500B in FIG. 5A) of the burst of pulses (e.g., burst of pulses 500A in FIG. 5A) generated during a plasma process to determine at least one voltage decay value. The at least one voltage decay value can be detected by use of one or more sensing elements that are coupled to one or more voltage sensing elements coupled to the substrate 103. The portion of a pulse of the voltage waveform may be an interval of time (e.g., between T₁ and T₂) within the pulse of the waveform 500B, and may correspond to a part of or the entirety of the ion current stage of the waveform 500B. In some embodiments, the portion of a pulse of the waveform may be chosen in order to avoid transition times for the pulse, such as the transition between the sheath collapse stage and the ion current stage (e.g., portion of the ion current stage just before time T₁ in FIG. 5A). For example, as shown in FIG. 5A, the portion of the pulse that is measured begins a short time after the beginning of the ion current phase, which is generally defined after the sheath formation stage of the voltage pulse has occurred (i.e., vertical drop just before the start of the ion current stage). In some embodiments, the initial voltage value during the ion current stage is a function of the voltage waveform setpoint set by the PV waveform generator 150. The method 300 may also include determining the voltage delta value during a portion of a pulse by use of the established initial voltage value and final voltage value measured voltage on a substrate 103 (e.g., final voltage minus initial voltage).

The method 300 may optionally include detecting at least one measured current value (e.g., C₁) during a portion of a pulse of the waveform 502B (FIG. 5B) by use of a sensor (e.g., current sensor in sensor assembly 170) that is configured to detect a current flowing between the PV waveform generator 150 and bias electrode 104. The portion of a pulse of the waveform may be measured at an initial point in time (e.g., T₁) within the waveform 502B, and may correspond to the beginning of the ion current stage of the waveform 502B. In some embodiments, the current sensor may be an in-line sensor disposed between the energy source (e.g., PV waveform generator 150) and a bias electrode 104, or a sensor disposed within the power delivery circuitry within the energy source.

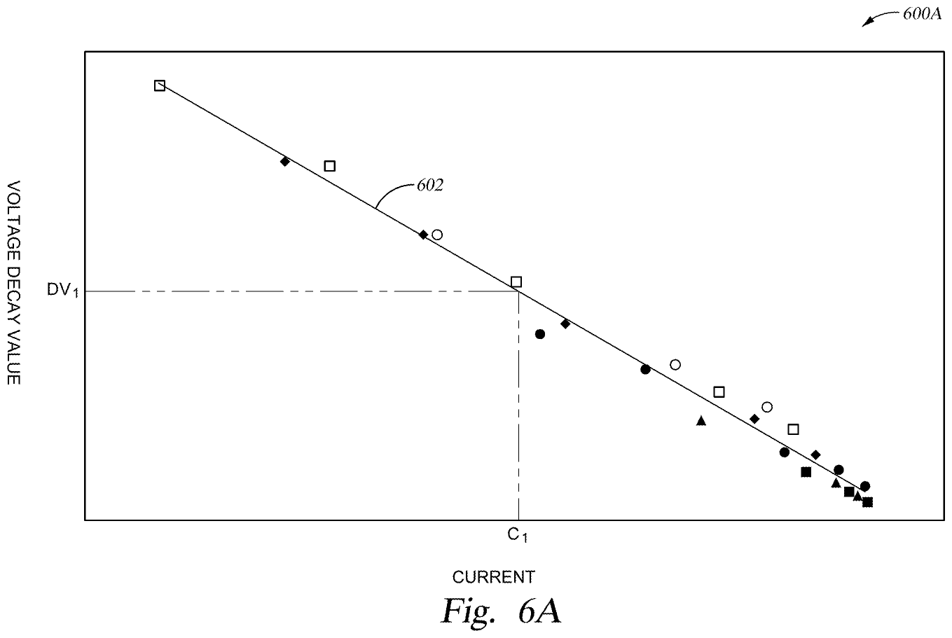

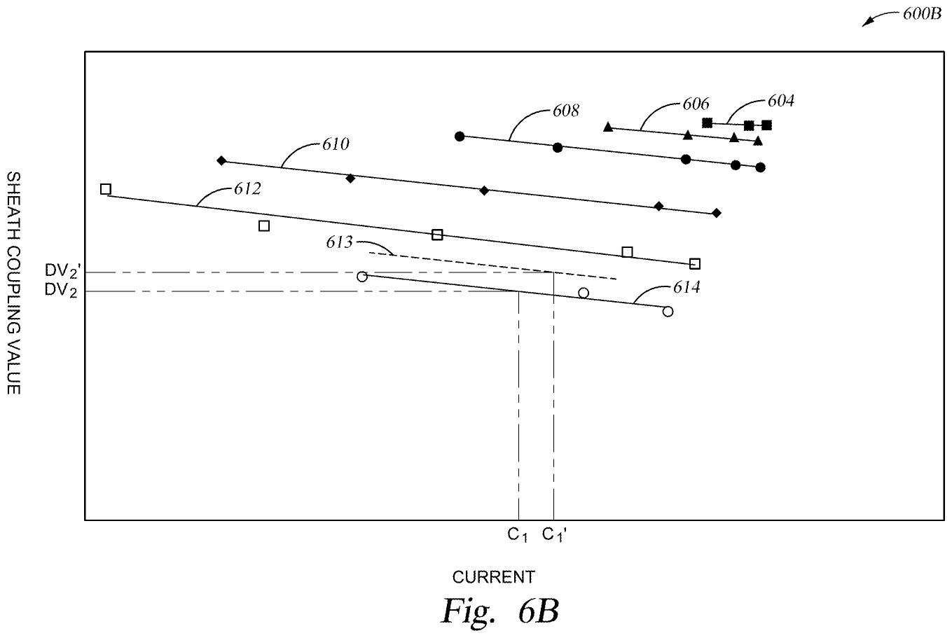

The method 300 may optionally include storing a plurality of voltage decay values that are a function of a generated measured current value (e.g., C₁). As illustrated in FIG. 6A, the stored plurality of voltage decay values can be used to form a curve 602 that represents a change in voltage (i.e., droop) on the substrate as a function of detected measured current value (e.g., C₁) during a portion of the ion current stage of the voltage waveform. The voltage decay values can be predetermined by measuring, by use of a wired wafer, the actual amount of voltage change (i.e., droop) in the voltage established on a substrate at a plurality of detected measured current values within a processing chamber at different plasma processing conditions, such as different pulse voltage biasing levels applied to the electrode by the PV waveform generator.

In some embodiments, the method 300 may include storing a plurality of sheath coupling values in memory. The sheath coupling values represent the relationship in capacitive coupling between a substrate and the biasing electrode when a voltage waveform is applied to an electrode (e.g., bias electrode) by the PV waveform generator 150. The sheath coupling values are a measure of the difference in a voltage established on a substrate relative to a voltage applied to the electrode at an instant in time at a measured current value (e.g., C₁ measured at T₁ in FIG. 5B). It has been found that sheath coupling values will vary as a function of the measured current value and the magnitude of the voltage applied to the electrode (e.g., initial voltage measured at time T₁). The generated initial voltage value is a function of the PV setpoint. For example, each curve (e.g., 604, 606, 608, 610, 612, 614) in FIG. 6B is associated with a different PV setpoint. The sheath coupling values can be determined by measuring voltage on a wired wafer, comparing the measured voltage with a voltage delivered to an electrode, and also noting a generated measured current value (e.g., C₁) at the same instant in time. One will note that the measured current value C₁ is based on or affected by the plasma processing chamber's response to the applied PV setpoint and the applied source power used to generate the plasma.

The voltage decay values and the sheath coupling values may be stored, for example, in a memory 192 of a system controller 126. The at least one voltage decay value and the at least one sheath coupling value may be stored, for example, in the form of a table, graph, equation, or any other available means for recording a relationship. For example, FIGS. 6A and 6B illustrate examples representing voltage decay values and sheath coupling values associated with measurements of a waveform as measured on a substrate 103 (e.g., voltage delta, measured current value), in accordance with certain embodiments of the present disclosure.

In FIG. 6A, graph 600A illustrates the relationship (e.g., voltage droop) between a voltage decay value (i.e., slope of voltage during ion current stage (dV/dt)) and a measured current value (e.g., C₁). In some embodiments, determining a voltage decay value during a portion of a pulse during the first waveform (see block 306) includes finding a matching value detected characteristic of a first waveform, such as the measured current value on the graph 600A, or current C₁, and then finding the corresponding voltage decay value (e.g., DV₁) based on the relationship set by curve 602. As noted above, the voltage decay values, which are stored in memory 192 as a function of the measured current value, can be stored in a table, graph or equation so that, when compared with the measured current value C₁, a voltage decay value DV₁ can be determined. In general, the single voltage decay value is a measure of the rate of the projected decay (i.e., droop) in the substrate voltage during the ion current phase of a voltage pulse based on a measured current value. In some embodiments, the determined voltage decay value DV₁ can be used directly during the subsequent compensation factor determination activity (block 308). In some other embodiments, based on the determined voltage decay value DV₁, a voltage delta (ΔV) can be determined by multiplying the determined voltage decay value DV₁ by a known length of the ion current stage in which the measured current value C₁ was measured. The length of the ion current stage is associated with the PV on-time of a voltage pulse.

In FIG. 6B, graph 600B is illustrates a relationship between an initial voltage and a measured current value (current_i) for various PV setpoints used to find a sheath coupling voltage value. Each of the curves 604, 606, 608, 610, 612, and 614 represent a single PV setpoint, and thus a sheath coupling voltage value (i.e., Y-axis) can be determined by knowledge of measured current value (i.e., X-axis) at a known PV setpoint. In the example illustrated in FIG. 6B, one will note that the magnitude of the PV setpoint (e.g., magnitude of the ion current voltage during the ion current stage) used to generate curves 604, 606, 608, 610, 612, and 614 decrease in magnitude from curve 604 to curve 614. In one example, a sheath coupling voltage value during the portion of the pulse of the first waveform (see block 306) can be determined by detecting a measured current value C₁ (amps) and finding the corresponding sheath coupling value DV₂ (volts) using a known PV setpoint illustrated by the curve 614 in the sheath coupling graph 600B. As noted above, the sheath coupling values, which are stored in memory 192 as a function of the measured current value, can be stored in a table, graph or equation such that when compared with the measured current value C₁ a single sheath coupling value can be determined. In some embodiments, multiple different sets of curves, such as two or more sets of curves 604, 606, 608, 610, 612, and 614, may be stored in memory and used and/or selected based on an adjustment of one or more different plasma processing parameters, such a source power, percentage on-time of the PV pulse, pulse frequency or other plasma processing parameter that will affect the sheath coupling values.

In some plasma processing processes performed on a substrate, it is desirable to adjust the PV setpoint to achieve a desired voltage on a substrate during the ion current phase of an applied PV pulse. In some cases, the actual desired PV setpoint needed to achieve a desired voltage and process result may not coincide with one of the generated curves 604, 606, 608, 610, 612, and 614, which are stored in memory and utilized to determine the sheath coupling value DV₂ (volts). In some embodiments, as illustrated in FIG. 6B, it is desirable to adjust the PV setpoint to a value that falls between two known curves, such as curves 612 and 614, to achieve a desired process result on a substrate during a plasma process performed thereon. The new PV setpoint is illustrated in FIG. 6B as the curve 613, which can be determined by interpolating at a measured current value C₁′ a point between the two known curves 612 and 614. Therefore, by use of the measured current value C₁′ (FIG. 6B) at the new PV setpoint and finding an interpolated PV setpoint value by use of the system controller 126 a new sheath coupling value DV₂′ (FIG. 6B) can be determined. Using this technique a new sheath coupling value DV₂′ can be determined for any desired PV setpoint.

At block 308, a compensation factor may be calculated based on the determined voltage delta (ΔV) determined from the voltage decay value DV₁ and the determined sheath coupling value DV₂. The compensation factor is calculated based on the voltage delta (ΔV) and a determined sheath coupling voltage value DV₂ is determined from information received by the detection of the measured current value C₁ during one or more pulses within a generated waveform. In some embodiments, the compensation factor is used to adjust the magnitude of the voltage applied during the ion current stage as a function of time based on the expected slope determined from the voltage decay value DV₁ and expected offset in voltage determined from the sheath coupling value DV₂. For example, FIG. 4, as described above, illustrates an example of an optimally compensated voltage waveform (e.g., 402, 404) established on a substrate 103, through the implementation of a voltage decay stepcount.

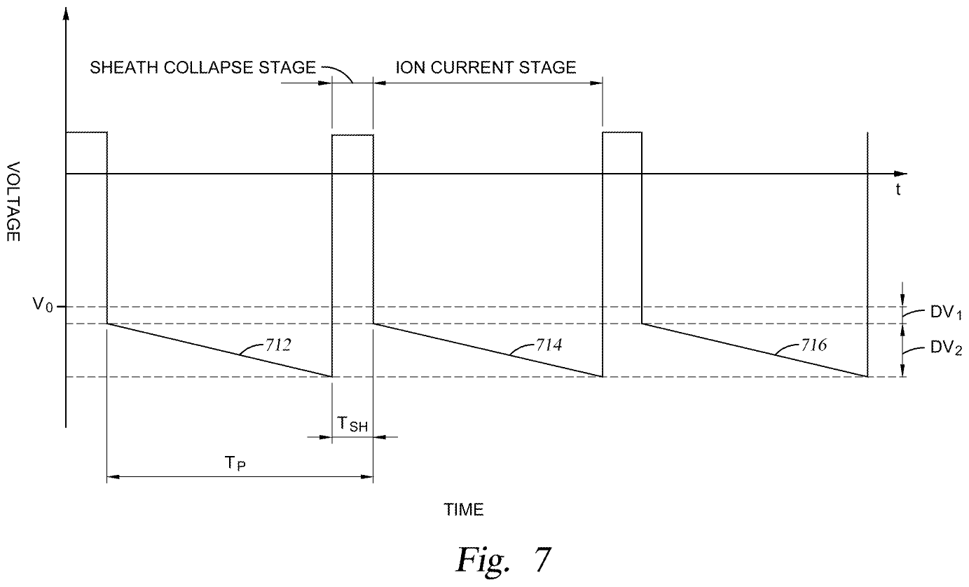

FIG. 7 shows an example of an effect of applying a compensation factor determined in block 308 to a voltage waveform that is applied to an electrode, such as the bias electrode 104 shown in FIG. 1 by use of the system controller 126. The waveform example shown in FIG. 7 generally includes two main stages, an ion current stage and a sheath collapse stage/ion neutralization stage that is applied to an electrode. At the beginning of the ion current stage, a drop in the applied voltage establishes a high voltage sheath above the substrate, which causes the positive ions formed in a plasma to flow to the surface of the substrate 103. As discussed previously, the charging of surface of substrate due to flow of the positive ions to the substrate surface generates the voltage droop.

Therefore, by applying the compensation factor determined in block 308 the slope of the waveform established on the substrate during the ion current stage can be adjust so that it is zero or close to zero to improve the ion energy distribution function (IEDF) created during the plasma process. An example, of compensated waveform is shown in FIG. 4B. The compensated portion of a voltage waveform that is delivered from the power supply (e.g., waveform generator 150) to the bias electrode 104 may include the portions of the waveform represented by lines 712, 714, 716 in FIG. 7.

In some embodiments, calculating the compensation factor involves using the voltage delta (ΔV) and the determined sheath coupling voltage value DV₂, along with the a known PV on-time found within a pulse of a voltage waveform. In some embodiments, the PV setpoint on-time of a waveform is stored in a memory 192, and may be used, along with the determined voltage decay value DV₁ and sheath coupling voltage value DV₂ to calculate the compensation factor. The determined sheath coupling voltage value DV₂ sets the offset in the voltage established at the substrate 103 during plasma processing, which as shown in FIG. 7, for example, includes an increased drop in voltage (e.g., more negative) an amount equal to the magnitude of sheath coupling voltage value DV₂ from the original voltage drop (V₀) formed during the sheath formation stage used in a prior pulse. For example, the sheath coupling voltage value DV₂ can be applied to an initial applied voltage V₀ generated by the power supply to shift the voltage to a compensated voltage value (e.g., V₀+DV₂) to enable a more optimized negative voltage to be applied at the start of the ion current phase. The voltage decay value DV₁ is also multiplied by the PV setpoint on-time value (seconds) to determine the voltage delta (ΔV) compensation required over the length of the PV on-time (e.g., the necessary slope of the curves 712, 714, 716) to enable a more optimized IEDF that compensates for the voltage decay (e.g., droop). Thus, in some cases, the compensation factor will include the amount of correction created by the determination of the sheath coupling voltage value DV₂ and the determined the voltage delta (ΔV) derived from the determined voltage decay value DV₁.

While the voltage delta (ΔV) compensation applied during the ion current phase is illustrated in FIG. 7 as a linear curve (e.g., first order curve) this configuration is not intended to be limiting as to the scope of the disclosure provided herein, since the compensation provided during the ion current phase can include a non-linear shape due to a need to better adjust the plasma processes performed during this phase of the PV pulse. In some examples, the voltage delta (ΔV) compensation provided during the ion current phase could include a second order, third order, fourth order or even a higher order correction (e.g., N^{th} order). In another example, the voltage delta (ΔV) compensation provided during the ion current phase could include breaking-up the compensation provided during the ion current phase into a series of interconnected sub-steps that form a staircase, spline, or other desired curve shape. In this example, each of the interconnected sub-steps can include a first order, a second order, third order, fourth order or an N^{th} order correction.

At block 310, the compensation factor is applied to correct for the voltage decay within a subsequent portion of the waveform, such as during one or more voltage pulses. Correcting for the voltage decay within a subsequent waveform may include adjusting the at least one characteristic (e.g., bias voltage, current C₁) using the compensation factor. In some embodiments, the compensation factor may be applied as a continuous slope. In some embodiments, rather than forming a linear ramp during the ion current stage, the calculated compensation factor may be used to determine a staircase like number of voltage decay steps and the length and/or size of each step to be applied during the ion current stage of each of pulses to correct for the voltage decay. In other words, the compensation factor may be applied in steps as a continuous voltage ramp or a non-linear voltage ramp. In some embodiments, the compensation factor may be applied to a subsequent waveform as a voltage decay step count (e.g., staircase like ramp correction). An example of a compensated waveform, established at the substrate, which includes three steps is shown in FIG. 4B.

In some embodiments, the voltage decay may be estimated during the processing of a wafer (e.g., substrate 103), and the compensation factor may be applied to correct for the voltage decay within a subsequent pulse of a burst for the wafer. In other embodiments, the voltage decay may be estimated during the processing of a wafer, and the compensation factor may be applied to correct for the voltage decay within a subsequent burst.

In some embodiments, the voltage decay may be estimated during the processing of a wafer (e.g., substrate 103), and the compensation factor may be applied to correct for the voltage decay within a subsequent waveform on a subsequent wafer. However, due to the stored voltage decay values and the sheath coupling values, the subsequent wafer need not be a wired wafer, the previously stored voltage decay values and the sheath coupling values may be relied upon to calculate the compensation factor.

In some examples, as illustrated in FIG. 7, the voltage waveforms can be delivered at a frequency (1/Tₚ), which is between about 50 kHz and 1000 kHz. The voltage waveform established at the electrode can have an on-time, which is defined as the ratio of the ion current time period (e.g., length of ion current stage) and the waveform period T_{P}, is greater than 50%, or greater than 70%, such as between 80% and 95%. A voltage waveform, which has a waveform cycle has a period T_{P} (e.g., about 2.5 μs), can be serially repeated within a waveform burst that has a burst period that is between about 100 microseconds (μs) and about 10 milliseconds (ms). The burst of PV waveforms can have a burst duty cycle that is between about 5%-100%, such as between about 50% and about 95%, wherein the duty cycle is the ratio of the burst period divided by the burst period plus a non-burst period (i.e., no PV waveforms are generated) that separates the burst periods. As shown, the sheath collapse stage may have a duration of TSH (e.g., off-time), which may be about 200 ns.

### Additional Considerations

As used herein, the term “coupled” is used to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A method for waveform generation, comprising:
delivering a first waveform with an associated setpoint from an energy source;
detecting at least one characteristic of the first waveform using at least one sensor;
determining a voltage decay value during a portion of a pulse provided within the first waveform by use of the detected at least one characteristic and at least one stored voltage decay value function;
determining a sheath coupling voltage value during the portion of the pulse of the first waveform by use of the detected at least one characteristic and at least one stored sheath coupling voltage value function;
calculating a compensation factor based on the determined voltage decay value and the determined sheath coupling voltage value; and
adjusting at least one characteristic of the first waveform by applying the calculated compensation factor to the at least one characteristic of the first waveform.

2. The method of claim 1, wherein the first waveform is a high voltage pulse waveform, and establishes a sheath.

3. The method of claim 1, wherein the associated setpoint is a baseline process, voltage and temperature (PVT) setpoint.

4. The method of claim 1, wherein the at least one characteristic is a current sensor metric.

5. The method of claim 1, wherein the at least one sensor is an in-line sensor and is included in a current transformer.

6. The method of claim 1, further comprising:
detecting at least one value associated with an initial voltage and at least one value associated with a final voltage during the portion of the pulse of the first waveform by using at least one second sensor coupled to a wired wafer;
determining at least one voltage delta value by using the at least one value associated with an initial voltage and the at least one value associated with a final voltage;
detecting at least one measured current value during the portion of the pulse of the first waveform by using the at least one sensor; and
storing the at least one stored voltage decay value representing a relationship between the at least one voltage delta value and the at least one measured current value.

7. The method of claim 6, further comprising:
storing the at least one stored sheath coupling voltage value representing a second relationship between the at least one value associated with an initial voltage and the at least one measured current value.

8. The method of claim 1, wherein a process, voltage and temperature (PVT) on-time of the first waveform is known.

9. The method of claim 1, wherein the compensation factor is a voltage decay step count.

10. The method of claim 1, wherein adjusting the at least one characteristic of the first waveform comprises applying a continuous voltage ramp to a portion of the pulse.

11. A waveform generator, comprising:
a sensor assembly coupled to an output of a pulser, wherein the sensor assembly comprises at least one sensor configured to detect at least one characteristic of a first waveform generated by the waveform generator; and
a system controller coupled to the waveform generator, wherein the system controller comprises:
a processor and memory, wherein the memory includes instructions which when executed by the processor causes:
an amount of voltage decay within a portion of a pulse during the first waveform to be determined using at least one stored voltage decay value function;
an amount of a sheath coupling voltage within the portion of a pulse of the first waveform to be determined using at least one stored sheath coupling voltage value function;
a compensation factor based on the determined amount of voltage decay and the determined amount of sheath coupling voltage to be calculated; and
the at least one characteristic of the first waveform to be adjusted based on the application of the calculated compensation factor.

12. The waveform generator of claim 11, wherein:
the first waveform is a high voltage pulse waveform, and
the first waveform establishes a sheath.

13. The waveform generator of claim 11, wherein the first waveform has an associated setpoint, and the associated setpoint is a baseline process, voltage and temperature (PVT) setpoint.

14. The waveform generator of claim 11, wherein the at least one characteristic is a current sensor metric.

15. The waveform generator of claim 11, wherein the at least one sensor is an in-line sensor.

16. The waveform generator of claim 11, wherein the memory includes further instructions which when executed by the processor causes:
at least one value associated with an initial voltage and at least one value associated with a final voltage during the portion of the first waveform to be determined by using at least one second sensor coupled to a wired wafer;
at least one voltage delta value to be determined by using the at least one value associated with an initial voltage and the at least one value associated with a final voltage;
at least one measured current value during the portion of the first waveform to be determined using the at least one sensor; and
the at least one stored voltage decay value function representing a relationship between the at least one voltage delta value and the at least one measured current value to be stored in the memory.

17. The waveform generator of claim 16, wherein the memory includes further instructions which when executed by the processor causes:
the at least one stored sheath coupling voltage value formulation representing a second relationship between the at least one value associated with an initial voltage and the at least one measured current value to be stored in the memory.

18. The waveform generator of claim 11, wherein a process, voltage and temperature (PVT) on-time of the first waveform is known.

19. The waveform generator of claim 11, wherein the compensation factor is a voltage decay step count.

20. The waveform generator of claim 11, wherein compensation factor is applied as a continuous voltage ramp or a non-linear voltage ramp.
